(19) United States
(12) Patent Application Publication
(10) Pub. No.: US 2018/0203950 A1
(43) Pub. Date: Jul. 19, 2018

(54) METHOD FOR PROVIDING PARAMETER FOR COIL DESIGN AND APPARATUS USING THE SAME

(71) Applicant: ELECTRONICS AND TELECOMMUNICATIONS RESEARCH INSTITUTE, Daejeon (KR)

(72) Inventors: Seung-Min CHOI, Daejeon (KR); Jae-Chan JEONG, Daejeon (KR); Hyo-Bong HONG, Daejeon (KR)

(21) Appl. No.: 15/868,863

(22) Filed: Jan. 11, 2018

(30) Foreign Application Priority Data
Jan. 18, 2017 (KR) 10-2017-0008515

(51) Int. Cl. G06F 17/50; G01R 33/10

(52) U.S. Cl. CPC G06F 17/50; H01F 41/04; G01R 33/10

(57) ABSTRACT

Disclosed herein are a method for providing a parameter for coil design and an apparatus for the same. The method includes receiving a magnetic field parameter value for an arbitrary coil from a user; determining whether there is a constraint on each of an electrical parameter group and a geometric parameter group; when it is determined that there is a constraint on any one of the two groups, setting a parameter range for a second parameter group on which there is no constraint based on a fixed parameter set of a first parameter group on which there is a constraint; and selecting a final parameter set of the second parameter group for satisfying the magnetic field parameter value within the parameter range and outputting parameter values of the fixed parameter set and the final parameter set to the user.

### CROSS REFERENCE TO RELATED APPLICATION

This application claims the benefit of Korean Patent Application No. 10-2017-0008515, filed Jan. 18, 2017, which is hereby incorporated by reference in its entirety into this application.

### BACKGROUND OF THE INVENTION

### 1. Technical Field

The present invention relates generally to technology for providing parameters for designing a coil, and more particularly to a method and apparatus for providing parameters for coil design in order to automatically and accurately design a coil for generating a magnetic field having a strength desired by a user.

### 2. Description of the Related Art

When a coil having applied thereto an AC signal having a frequency is designed, it is necessary to consider electrical characteristics generated depending on the geometry of the coil, such as resistance, inductance, capacitance, and the like. Impedance may be calculated using such electrical characteristics, and with the maximum voltage and the maximum current of a power supply device, the value of current that is actually supplied from the power supply device to the coil may be estimated.

Here, the strength (H) of a magnetic field at a certain point inside or outside a coil may be calculated using a Biot-Savart law. Here, the Biot-Savart law is a physical law stating that a magnetic field generated by a given current is perpendicular to the direction of current flow and that the strength thereof is inversely proportional to the square of the distance from the current element that produces the magnetic field in electromagnetics. The Biot-Savart law shows that a magnetic field is related to the intensity and the direction of current and the length of wire through which the current flows. That is, the number of turns per unit length of a coil, which is set when the coil is designed, and current flowing through the coil are related to the strength of a magnetic field generated from the coil.

Accordingly, in order to calculate the strength of a magnetic field generated from a coil, it is necessary to consider physical quantities, such as the power supply capacity of a power supply device, a ratio between the value of current and the strength of the magnetic field depending on the geometry of the coil, impedance depending on the geometry of the coil, and the value of current that actually flows in the coil depending on the power supply capacity of the power supply device.

However, it is difficult to accurately design a desired coil in consideration of all of these physical quantities, and it is time-consuming to accurately generate a coil for achieving a desired magnetic field strength. With regard to this, Korean Patent No. 10-1634650, published on Jun. 23, 2016, discloses a technology related to “Method and apparatus for designing optimized non-contact high-power supply coil and pick-up coil.”

### SUMMARY OF THE INVENTION

An object of the present invention is to provide information about parameters in order to enable a user to easily design a desired coil.

Another object of the present invention is to automatically provide design information in order to enable a user to quickly generate a desired coil.

A further object of the present invention is to enable a user to design an optimum coil in a restricted environment by considering constraints when the coil is designed.

In order to accomplish the above objects, a method for providing a parameter for coil design according to the present invention includes receiving a magnetic field parameter value for an arbitrary coil from a user; determining whether there is a constraint on each of an electrical parameter group and a geometric parameter group, which are necessary in order to design the arbitrary coil; when it is determined that there is a constraint on either the electrical parameter group or the geometric parameter group, setting a parameter range for a second parameter group on which there is no constraint based on a fixed parameter set of a first parameter group on which there is a constraint; and selecting a final parameter set of the second parameter group for satisfying the magnetic field parameter value within the parameter range and outputting parameter values of the fixed parameter set and the final parameter set to the user.

Here, outputting the parameter values may include extracting multiple candidate parameter sets for selecting the final parameter set therefrom; and selecting a candidate parameter set that is capable of generating a magnetic field that is closest to the magnetic field parameter value as the final parameter set, among the multiple candidate parameter sets.

Here, selecting the candidate parameter set may include calculating a strength of each of multiple magnetic fields that are capable of being generated based on the fixed parameter set and the multiple candidate parameter sets; and detecting a most similar magnetic field that satisfies a condition in which an absolute value of a difference between a strength thereof and the magnetic field parameter value is smallest, among the multiple magnetic fields, and a candidate parameter set that generates the most similar magnetic field may be selected as the final parameter set, among the multiple candidate parameter sets.

Here, the method may further include acquiring a fixed electrical parameter set for the electrical parameter group and a fixed geometric parameter set for the geometric parameter group when it is determined that there are constraints on both the electrical parameter group and the geometric parameter group; and outputting parameter values of the fixed electrical parameter set and parameter values of the fixed geometric parameter set to the user.

The method may further include setting an electrical parameter range for the electrical parameter group and a geometric parameter range for the geometric parameter group when it is determined that there is no constraint on any of the electrical parameter group and the geometric parameter group; selecting a final electrical parameter set of the electrical parameter group for satisfying the magnetic field parameter value within the electrical parameter range and a final geometric parameter set of the geometric parameter group for satisfying the magnetic field parameter value within the geometric parameter range; and outputting parameter values of the final electrical parameter set and parameter values of the final geometric parameter set to the user.

Here, the fixed parameter set may include fixed values respectively for multiple first parameters included in the first parameter group, and the final parameter set may include final parameter values respectively for multiple second parameters included in the second parameter group.

Here, calculating the strength may be configured to calculate the strength of each of the multiple magnetic fields using a Biot-Savart law.

Here, the magnetic field parameter value may be a strength of a magnetic field at any coordinates in a region of a magnetic field generated from the arbitrary coil.

Here, determining whether there is a constraint may include determining whether there is a constraint on the electrical parameter group based on a power supply module for supplying power to the coil; and determining whether there is a constraint on the geometric parameter group depending on whether the coil has been developed.

Here, the electrical parameter group may include a parameter corresponding to at least one of a maximum voltage, a supplied voltage, a maximum current, and a frequency, and the geometric parameter group may include a parameter corresponding to at least one of a diameter of the arbitrary coil, an inner radius thereof, and a height or a length thereof.

Also, an apparatus for providing a parameter for coil design according to an embodiment of the present invention includes an input unit for receiving a magnetic field parameter value for an arbitrary coil from a user; a determination unit for determining whether there is a constraint on each of an electrical parameter group and a geometric parameter group, which are necessary in order to design the arbitrary coil; a control unit for setting a parameter range for a second parameter group on which there is no constraint based on a fixed parameter set of a first parameter group on which there is a constraint when it is determined that there is a constraint on either the electrical parameter group or the geometric parameter group, and for selecting a final parameter set of the second parameter group for satisfying the magnetic field parameter value within the parameter range; and an output unit for outputting parameter values of the fixed parameter set and the final parameter set to the user.

Here, the control unit may include a candidate parameter set extraction unit for extracting multiple candidate parameter sets for selecting the final parameter set therefrom; and the control unit may select a candidate parameter set that is capable of generating a magnetic field that is closest to the magnetic field parameter value as the final parameter set, among the multiple candidate parameter sets.

Here, the control unit may further include a magnetic field calculation unit for calculating a strength of each of multiple magnetic fields that are capable of being generated based on the fixed parameter set and the multiple candidate parameter sets; and a similar magnetic field detection unit for detecting a most similar magnetic field that satisfies a condition in which an absolute value of a difference between a strength thereof and the magnetic field parameter value is smallest, among the multiple magnetic fields, and the control unit may select a candidate parameter set that generates the most similar magnetic field as the final parameter set, among the multiple candidate parameter sets.

Here, when it is determined that there are constraints on both the electrical parameter group and the geometric parameter group, the output unit may output parameter values of a fixed electrical parameter set for the electrical parameter group and parameter values of a fixed geometric parameter set for the geometric parameter group to the user.

Here, when there is no constraint on any of the electrical parameter group and the geometric parameter group, the control unit may set an electrical parameter range for the electrical parameter group and a geometric parameter range for the geometric parameter group and select a final electrical parameter set of the electrical parameter group for satisfying the magnetic field parameter value within the electrical parameter range and a final geometric parameter set of the geometric parameter group for satisfying the magnetic field parameter value within the geometric parameter range.

Here, when there is no constraint on any of the electrical parameter group and the geometric parameter group, the output unit may output parameter values of the final electrical parameter set and parameter values of the final geometric parameter set to the user.

Here, the fixed parameter set may include fixed values respectively for multiple first parameters included in the first parameter group, and the final parameter set may include final parameter values respectively for multiple second parameters included in the second parameter group.

Here, the magnetic field calculation unit may calculate the strength of each of the multiple magnetic fields using a Biot-Savart law.

Here, the magnetic field parameter value may be a strength of a magnetic field at any coordinates in a region of a magnetic field generated from the arbitrary coil.

Here, the electrical parameter group may include a parameter corresponding to at least one of a maximum voltage, a supplied voltage, a maximum current, and a frequency, and the geometric parameter group may include a parameter corresponding to at least one of a diameter of the arbitrary coil, an inner radius thereof, and a height or a length thereof.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a flowchart that shows a method for providing a parameter for coil design according to an embodiment of the present invention;

FIG. 2 is a view that shows an example of a geometric parameter of a coil according to the present invention;

FIG. 3 is a view that shows an example of the top face of the bobbin and the coil illustrated in FIG. 2;

FIG. 4 is a view that shows an example of a parameter group according to the present invention;

FIG. 5 is a view that shows an example of the calculation of magnetic field strength using a Biot-Savart law;

FIG. 6 is a block diagram that shows an apparatus for providing a parameter for coil design according to an embodiment of the present invention;

FIG. 7 is a block diagram that shows an example of the control unit illustrated in FIG. 6;

FIG. 8 is a flowchart that specifically shows a method for providing a parameter for coil design according to an embodiment of the present invention; and

FIG. 9 is an embodiment of the present invention implemented in a computer system.

### DESCRIPTION OF THE PREFERRED EMBODIMENTS

The present invention will be described in detail below with reference to the accompanying drawings. Repeated descriptions and descriptions of known functions and configurations which have been deemed to make the gist of the present invention unnecessarily obscure will be omitted below. The embodiments of the present invention are intended to fully describe the present invention to a person having ordinary knowledge in the art to which the present invention pertains. Accordingly, the shapes, sizes, etc. of components in the drawings may be exaggerated in order to make the description clearer.

Hereinafter, a preferred embodiment of the present invention will be described in detail with reference to the accompanying drawings.

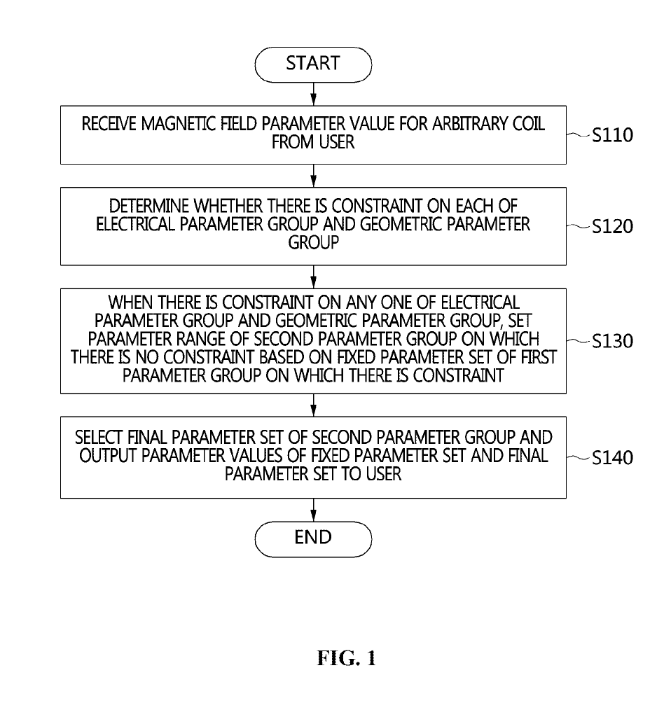

FIG. 1 is a flowchart that shows a method for providing a parameter for coil design according to an embodiment of the present invention.

Referring to FIG. 1, in the method for providing a parameter for coil design according to an embodiment of the present invention, a magnetic field parameter value for an arbitrary coil is received from a user at step S110.

Here, the arbitrary coil may be a solenoid coil that is formed by winding general wire around a cylindrical form. Accordingly, when current or voltage is applied to the arbitrary coil, a magnetic field may be generated inside or outside the solenoid coil.

Here, the above-mentioned solenoid coil may have various forms. For example, the form of a solenoid coil may be categorized depending on whether an iron core is present in the center of the solenoid coil, whether the coil is a single coil or multiple coils, the shape of a cross section, the thickness of the wire used for the coil, the number of turns per unit length, whether the coil is a single-layer coil or a multi-layer coil, and the like.

Accordingly, it is difficult to take examples of all of the various forms of solenoid coils in order to describe the present invention, and an embodiment in which the cross section of a solenoid coil is circular will be described for the convenience of understanding.

Here, a user may input a parameter value for a magnetic field to be generated from a solenoid coil.

Here, the magnetic field parameter value may denote the strength of a magnetic field at any point in a region of the magnetic field generated from the arbitrary coil. For example, the point may be represented in the form of coordinates (x, y, z) based on the center point of the arbitrary coil, which is set by a user.

Also, in the method for providing a parameter for coil design according to an embodiment of the present invention, whether there is a constraint on each of an electrical parameter group and a geometric parameter group, which are necessary in order to design the arbitrary coil, is determined at step S120.

Here, the electrical parameter group and the geometric parameter group may be defined by categorizing parameters that are necessary when a user designs the coil.

Here, whether there is a constraint on the electrical parameter group may be determined based on a power supply module for supplying power to the coil. Here, depending on the application, there may be no constraint on parameter values in the electrical parameter group and the geometric parameter group, there may be a constraint on parameter values in only one of the electrical parameter group and the geometric parameter group, or there may be a constraint on parameter values in both the electrical parameter group and the geometric parameter group.

Here, whether there is a constraint on the electrical parameter group may be determined based on the power supply module for supplying power to the coil.

For example, when it is difficult to change the values of electrical parameters because the development of the power supply module is completed, it may be determined that the electrical characteristics of power to be supplied to the coil by a user are set as constraints.

Here, the electrical parameter group may include a parameter corresponding to at least one of the maximum voltage, a supplied voltage, the maximum current, and a frequency.

Here, whether there is a constraint on the geometric parameter group may be determined depending on whether the coil has been developed.

For example, when it is difficult to change the form of a coil because the development thereof is completed, it may be determined that the geometric parameter values of the coil are set as constraints.

Here, the geometric parameter group may include a parameter corresponding to at least one of the diameter, the inner radius, and the height or length of a coil.

Also, in the method for providing a parameter for coil design according to an embodiment of the present invention, there may be an electrical parameter group that is defined depending on the parameter values of the geometric parameter group. For example, a supplied current, the inductance of a coil, the capacitance thereof, the resistance thereof, the impedance thereof, and the like may be included.

Also, in the method for providing a parameter for coil design according to an embodiment of the present invention, when it is determined that there is a constraint on one of the electrical parameter group and the geometric parameter group, a parameter range for a second parameter group on which there is no constraint is set at step S130 based on a fixed parameter set of a first parameter group on which there is a constraint.

For example, when there is a constraint on the electrical parameter group, a parameter range for setting the parameter values of the geometric parameter group may be set based on the fixed parameter values of the electrical parameter group. Conversely, when there is a constraint on the geometric parameter group, a parameter range for setting the parameter values of the electrical parameter group may be set based on the fixed parameter values of the geometric parameter group.

Also, in the method for providing a parameter for coil design according to an embodiment of the present invention, a final parameter set of the second parameter group for satisfying the magnetic field parameter value within the parameter range is selected, and the parameter values of the fixed parameter set and those of the final parameter set are output to the user at step S140.

Here, the final parameter set may include parameter values based on which a magnetic field can be generated so as to correspond to the magnetic field parameter value within the parameter range. For example, when a coil is formed so as to correspond to the parameter values included in the final parameter set and the fixed parameter set, a magnetic field corresponding to the magnetic field parameter value, input by a user, may be generated. That is, a magnetic field having a desired strength may be generated at a specific point.

Here, multiple candidate parameter sets for selecting the final parameter set therefrom may be extracted.

Here, the candidate parameter sets may be generated within the parameter range. That is, various parameter sets that can be applied to a coil are generated, and the parameter set that is most suitable for achieving the magnetic field parameter value may be selected as the final parameter set.

Here, among the multiple candidate parameter sets, a candidate parameter set based on which the magnetic field that is closest to the magnetic field parameter value can be generated may be selected as the final parameter set.

Here, the strengths of multiple magnetic fields that can be generated based on the fixed parameter set and the multiple candidate parameter sets may be calculated.

Here, the strength of each of the multiple magnetic fields may be calculated using a Biot-Savart law.

Here, even though the geometry of an arbitrary coil is complicated, the effect of a magnetic field at a certain point generated from the coil may be calculated using a Biot-Savart law. Particularly, when the Boundary Element Method (BEM) or the Finite Element Method (FEM) is used, the effect of a magnetic field may be calculated using an improved computing device; however, this is time-consuming.

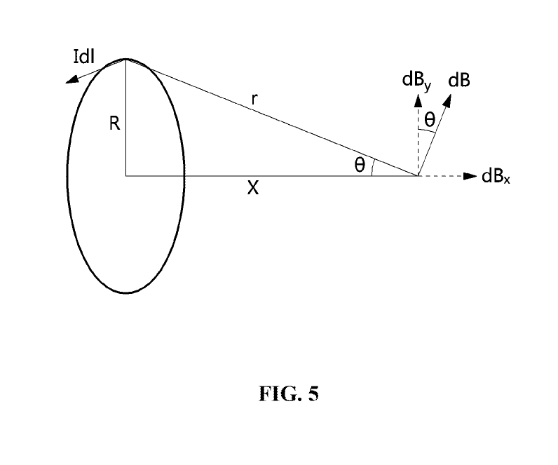

Here, the process of calculating the strength of a magnetic field based on a Biot-Savart law will be described later with reference to FIG. 5.

Here, among the multiple magnetic fields, the most similar magnetic field that satisfies a condition in which the absolute value of the difference between the strength thereof and the magnetic field parameter value is smallest may be detected.

Here, among the multiple candidate parameter sets, the candidate parameter set that can generate the most similar magnetic field may be selected as the final parameter set.

For example, assume that an objective function F for calculating the absolute value of the difference between the magnetic field parameter value, which is input by a user, and the strength of each of the multiple magnetic fields is defined, and that all possible parameter sets are defined as multiple domains of the objective function F. Here, a domain is set within the parameter range in order to improve the calculation speed and to avoid being trapped in a local minimum, whereby the total computational load may be decreased and a local minimum error may be prevented. That is, multiple candidate parameter sets corresponding to some of all possible parameter sets may be defined as the domain. Then, when the objective function is calculated, the result thereof may be created in the form of an array. When each value included in this array is called energy, the index of an element containing the minimum energy (cost) in the array is found, whereby the final parameter set may be selected.

Here, the fixed parameter set may include fixed values respectively for multiple first parameters included in the first parameter group, and the final parameter set may include final parameter values respectively for multiple second parameters included in the second parameter group.

Here, the final parameter values may satisfy the parameter range.

Also, although not illustrated in FIG. 1, in the method for providing a parameter for coil design according to an embodiment of the present invention, when there are constraints on both the electrical parameter group and the geometric parameter group, a fixed electrical parameter set for the electrical parameter group and a fixed geometric parameter set for the geometric parameter group are acquired, and the parameter values of the fixed electrical parameter set and the parameter values of the fixed geometric parameter set may be output to the user.

In this case, the user may adjust only the voltage and the frequency for the coil.

Also, although not illustrated in FIG. 1, in the method for providing a parameter for coil design according to an embodiment of the present invention, when there is no constraint on any of the electrical parameter group and the geometric parameter group, an electrical parameter range for the electrical parameter group and a geometric parameter range for the geometric parameter group may be set.

That is, because there is no fixed parameter, a parameter range for selecting a parameter set of each of the electrical parameter group and the geometric parameter group may be set.

Then, in order to satisfy the magnetic field parameter value within the parameter range, the final electrical parameter set for the electrical parameter group and the final geometric parameter set for the geometric parameter group are selected, and the parameter values thereof may be output to the user.

Also, although not illustrated in FIG. 1, in the method for providing a parameter for coil design according to an embodiment of the present invention, various kinds of information generated during the above-described process of providing parameters is stored.

Through the above-mentioned method for providing a parameter, information about parameters may be provided in order to enable a user to easily design a desired coil.

Also, design information may be automatically provided in order to enable a user to quickly generate a desired coil, and because constraints are considered when the coil is designed, an optimum coil desired by the user may be designed in a restricted environment.

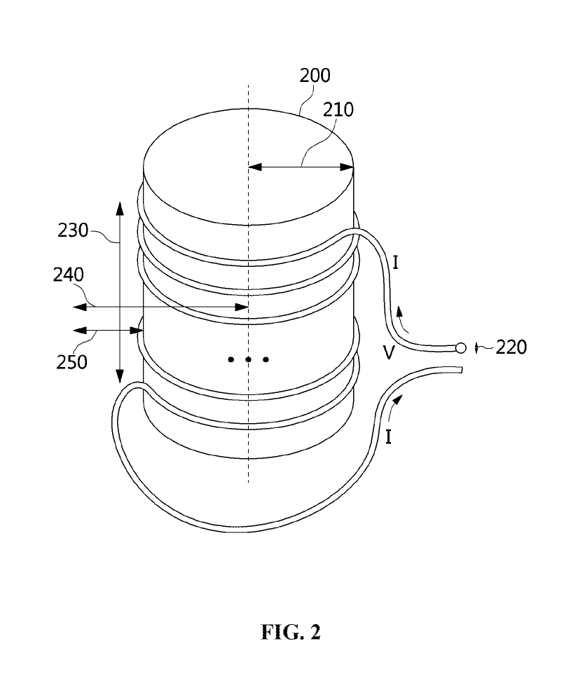

FIG. 2 is a view that shows an example of the geometric parameters of a coil according to the present invention.

Referring to FIG. 2, the geometric parameters of a coil according to the present invention may include the inner radius 210 of a solenoid coil formed by winding wire around a cylindrical bobbin 200, the diameter 220 of wire that is wound in order to form the solenoid coil, the length 230 of the solenoid coil, the radius 240 of the solenoid coil, the thickness 250 of the solenoid coil, and the like.

Here, the inner radius 210 of the solenoid coil may be the radius of the cylindrical bobbin 200.

Here, the solenoid coil illustrated in FIG. 2 is formed by winding a single piece of wire in the same direction, but a solenoid coil may be formed as a single coil or multiple coils depending on the circumstances. Also, in the case of multiple coils, the coil may be generated in various forms, such as a Maxwell coil, a Helmholtz coil and the like.

Here, the thickness 250 of the solenoid coil may be represented using the diameter 220 of wire or the number of layers of wire. For example, the thickness 250 may indicate whether the bobbin 200 is wound with a single layer of wire or multiple layers of wire.

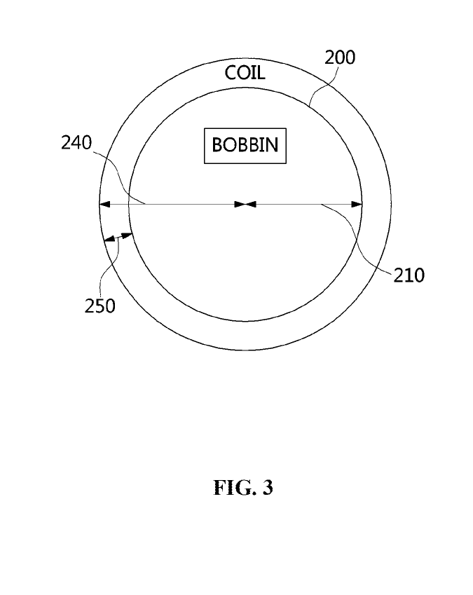

FIG. 3 is a view that shows an example of the top face of the bobbin and the coil illustrated in FIG. 2.

Referring to FIG. 3, the radius of the bobbin 200 illustrated in FIG. 2 is the inner radius 210 of the solenoid coil.

Also, the sum of the radius of the bobbin 200 and the diameter 220 of wire may be equal to the radius 240 of the solenoid coil.

If the bobbin 200 is wound with two layers of wire, the radius 240 of the solenoid coil may be equal to the sum of the radius of the bobbin 200 and twice the diameter 220 of the wire.

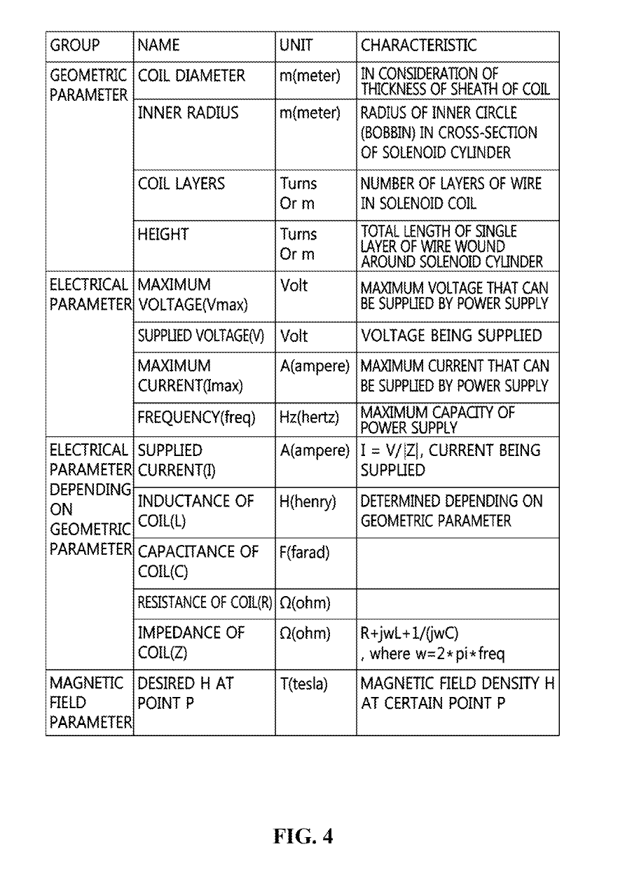

FIG. 4 is a view that shows an example of a parameter group according to the present invention.

FIG. 4 shows a parameter table 400 that contains electrical parameters and geometric parameters that are necessary when a coil is designed according to the present invention.

Here, some of the parameters in the parameter table 400 may have fixed values depending on whether there is a constraint, and the values of some parameters may not be fixed.

Here, when a parameter is not fixed, a range constraint is set in order to prevent the value of the parameter from diverging.

In the present invention, based on the value of the magnetic field parameter, among the parameters illustrated in FIG. 4, an optimum combination of parameters may be found and output in order to design a coil for achieving a desired magnetic field strength (Desired H), which is input by a user, at a point p.

Here, when a combination of parameters is output to a user, an index in which the value of a parameter can be input may be added in the parameter table shown in FIG. 4, but the method is not limited thereto.

FIG. 5 is a view that shows an example of the calculation of a magnetic field strength using a Biot-Savart law.

Referring to FIG. 5, the strength of a magnetic field at a certain point generated from a coil may be calculated using a Biot-Savart law.

Here, the Biot-Savart law is a physical law stating that a magnetic field generated by a given current is perpendicular to the direction of current flow and that the strength thereof is inversely proportional to the square of the distance from the current element that produces the magnetic field in electromagnetics, and shows that a magnetic field is related to the intensity and the direction of current and the length of wire through which the current flows.

Hereinafter, the process of calculating the strength of a magnetic field at a certain point using a Biot-Savart law will be described.

According to the Biot-Savart law, if current I flows through an infinitesimally short length of wire dl, a magnetic field density dB(r) at the origin point (r=0) due to the current flowing through the infinitesimally short length of wire may be calculated as shown in the following Equation (1):

$$d B ( r ) = \frac{{μ}_{0}}{4 π} \frac{Idl \times \hat{r}}{{r}^{2}} \qquad ( 1 )$$

where \hat{r}=r/r denotes a unit vector in the direction of r, and μ₀ denotes the permeability of free space.

Therefore, when both sides of this equation are integrated, the total strength of a magnetic field generated due to the current may be calculated.

The Biot-Savart law may also be used to calculate the strength of a magnetic field at the center of a circular current loop.

For example, as shown in FIG. 5, there is a circular current loop, and the current Idl is coming out of the page and is perpendicular to the axis X. Also, dB is perpendicular to the axis X. Here, because r²=x²+R² is satisfied according to the Pythagorean theorem, the following Equation (2) may be derived based on the Biot-Savart law:

$$d B ( r ) = \frac{{μ}_{0}}{4 π} \frac{Idl}{{r}^{2}} = \frac{{μ}_{0}}{4 π} \frac{Idl}{{x}^{2} + {R}^{2}} \qquad ( 2 )$$

Here, when magnetic fields dB generated due to current elements Idl around the circular current loop are added along the axis, because the y component of dB, which is perpendicular to the axis, is cancelled, only the x component of dB is calculated, as shown in the following Equation (3):

$$d {B}_{x} = d B sin θ = d B \frac{R}{r} = d B \frac{R}{\sqrt{{x}^{2} + {R}^{2}}} = \frac{{μ}_{0}}{4 π} \frac{RIdl}{{( {x}^{2} + {R}^{2} )}^{\frac{3}{2}}} \qquad ( 3 )$$

Here, because ∫dl=2πR, when X=0,

$${B}_{x} = \frac{{μ}_{0} I}{2 R}$$

may be satisfied.

When wire that generates a circular current loop forms a complicated coil, the number of turns of wire may be multiplied for the convenience of calculation, or a Boundary Element Method (BEM) or a Finite Element Method (FEM) may be used.

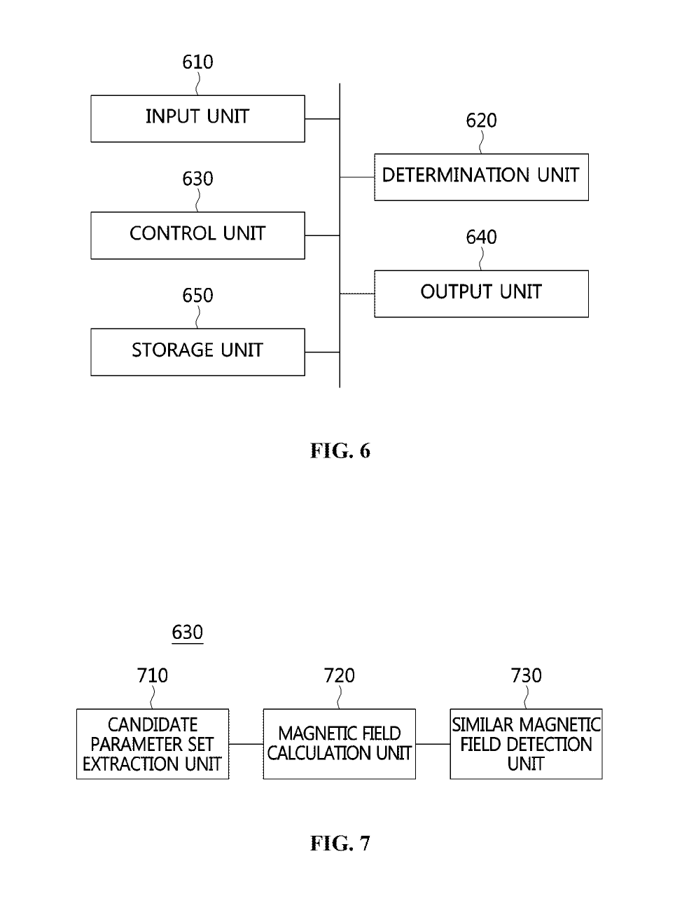

FIG. 6 is a block diagram that shows an apparatus for providing a parameter for coil design according to an embodiment of the present invention.

Referring to FIG. 6, the apparatus for providing a parameter for coil design according to an embodiment of the present invention includes an input unit 610, a determination unit 620, a control unit 630, an output unit 640, and a storage unit 650.

The input unit 610 receives a magnetic field parameter value for an arbitrary coil from a user.

Here, the arbitrary coil may be a solenoid coil that is formed by winding general wire around a cylindrical form. Accordingly, when current or voltage is applied to the arbitrary coil, a magnetic field may be generated inside or outside the solenoid coil.

Here, the above-mentioned solenoid coil may have various forms. For example, the form of a solenoid coil may be categorized depending on whether an iron core is present in the center of the solenoid coil, whether the coil is a single coil or multiple coils, the shape of a cross section, the thickness of the wire used for the coil, the number of turns per unit length, whether the coil is a single-layer coil or a multi-layer coil, and the like.

Accordingly, it is difficult to take examples of all of the various forms of solenoid coils in order to describe the present invention, and an embodiment in which the cross section of a solenoid coil is circular will be described for the convenience of understanding.

Here, a user may input a parameter value for a magnetic field to be generated from a solenoid coil.

Here, the magnetic field parameter value may denote the strength of a magnetic field at any point in a region of the magnetic field generated from the arbitrary coil. For example, the point may be represented in the form of coordinates (x, y, z) based on the center point of the arbitrary coil, which is set by a user.

The determination unit 620 determines whether there is a constraint on each of an electrical parameter group and a geometric parameter group, which are necessary in order to design the arbitrary coil.

Here, the electrical parameter group and the geometric parameter group may be defined by categorizing parameters that are necessary when a user designs a coil.

Here, whether there is a constraint on the electrical parameter group may be determined based on a power supply module for supplying power to the coil. Here, depending on the application, there may be no constraint on parameter values in any of the electrical parameter group and the geometric parameter group, there may be a constraint on parameter values in either the electrical parameter group or the geometric parameter group, or there may be a constraint on parameter values in both the electrical parameter group and the geometric parameter group.

Here, whether there is a constraint on the electrical parameter group may be determined based on the power supply module for supplying power to the coil.

For example, when it is difficult to change the values of electrical parameters because the development of the power supply module is completed, it may be determined that the electrical characteristics of power to be supplied to the coil by a user are set as constraints.

Here, the electrical parameter group may include a parameter corresponding to at least one of the maximum voltage, a supplied voltage, the maximum current, and a frequency.

Here, whether there is a constraint on the geometric parameter group may be determined depending on whether the coil has been developed.

For example, when it is difficult to change the form of a coil because the development thereof is completed, it may be determined that the geometric parameter values of the coil are set as constraints.

Here, the geometric parameter group may include a parameter corresponding to at least one of the diameter, the inner radius, and the height or length of a coil.

Also, there may be an electrical parameter group that is defined depending on the parameter values of the geometric parameter group. For example, a supplied current, the inductance of a coil, the capacitance thereof, the resistance thereof, the impedance thereof, and the like may be included.

The control unit 630 sets a parameter range for a second parameter group on which there is no constraint based on a fixed parameter set of a first parameter group on which there is a constraint when there is a constraint on any one of the electrical parameter group and the geometric parameter group, and sets a final parameter set of the second parameter group for satisfying the magnetic field parameter value within the parameter range.

For example, when there is a constraint on the electrical parameter group, a parameter range for setting the parameter values of the geometric parameter group may be set based on the fixed parameter values of the electrical parameter group. Conversely, when there is a constraint on the geometric parameter group, a parameter range for setting the parameter values of the electrical parameter group may be set based on the fixed parameter values of the geometric parameter group.

Here, the final parameter set may include parameter values based on which a magnetic field can be generated so as to correspond to the magnetic field parameter value within the parameter range. For example, when a coil is formed so as to correspond to the parameter values included in the final parameter set and the fixed parameter set, a magnetic field corresponding to the magnetic field parameter value, input by a user, may be generated. That is, a magnetic field having a desired strength may be generated at a specific point.

Here, multiple candidate parameter sets for selecting the final parameter set therefrom may be extracted.

Here, the candidate parameter sets may be generated within the parameter range. That is, various parameter sets that can be applied to a coil are generated, and the parameter set that is most suitable for achieving the magnetic field parameter value may be selected as the final parameter set.

Here, among the multiple candidate parameter sets, a candidate parameter set based on which a magnetic field that is closest to the magnetic field parameter value can be generated may be selected as the final parameter set.

Here, the strengths of multiple magnetic fields that can be generated based on the fixed parameter set and the multiple candidate parameter sets may be calculated.

Here, the strength of each of the multiple magnetic fields may be calculated using a Biot-Savart law.

Here, even though the geometry of an arbitrary coil is complicated, the effect of a magnetic field at a certain point generated from the coil may be calculated using the Biot-Savart law. Particularly, when the Boundary Element Method (BEM) or the Finite Element Method (FEM) is used, the effect of a magnetic field may be calculated using an improved computing device; however, this is time-consuming.

Here, the process of calculating the strength of a magnetic field based on a Biot-Savart law has been described with reference to FIG. 5.

Here, among the multiple magnetic fields, the most similar magnetic field that satisfies a condition in which the absolute value of the difference between the strength thereof and the magnetic field parameter value is smallest may be detected.

Here, among the multiple candidate parameter sets, the candidate parameter set that can generate the most similar magnetic field may be selected as the final parameter set.

For example, assume that an objective function F for calculating the absolute value of the difference between the magnetic field parameter value, which is input by a user, and the strength of each of the multiple magnetic fields is defined, and that all possible parameter sets are defined as multiple domains of the objective function F. Here, a domain is set within the parameter range in order to improve the calculation speed and to avoid being trapped in a local minimum, whereby the total computational load may be decreased and a local minimum error may be prevented. That is, multiple candidate parameter sets corresponding to some of all possible parameter sets may be defined as the domain. Then, when the objective function is calculated, the result thereof may be created in the form of an array. When each value included in this array is called energy, the index of an element containing the minimum energy (cost) in the array is found, whereby the final parameter set may be selected.

Here, the fixed parameter set may include fixed values respectively for multiple first parameters included in the first parameter group, and the final parameter set may include final parameter values respectively for multiple second parameters included in the second parameter group.

Here, the final parameter values may satisfy the parameter range.

Also, when there are constraints on both the electrical parameter group and the geometric parameter group, a fixed electrical parameter set for the electrical parameter group and a fixed geometric parameter set for the geometric parameter group are acquired, and the parameter values of the fixed electrical parameter set and those of the fixed geometric parameter set may be output to the user.

In this case, the user may adjust only the voltage and the frequency for the coil.

Also, when there is no constraint on either of the two groups, an electrical parameter range for the electrical parameter group and a geometric parameter range for the geometric parameter group may be set.

That is, because there is no fixed parameter, a parameter range for selecting a parameter set for each of the electrical parameter group and the geometric parameter group may be set.

Then, in order to satisfy the magnetic field parameter value within the parameter range, the final electrical parameter set for the electrical parameter group and the final geometric parameter set for the geometric parameter group are selected, and the parameter values thereof may be output to the user.

The output unit 640 outputs the parameter values of the fixed parameter set and the final parameter set to the user.

The storage unit 650 stores various kinds of information generated in the apparatus for providing a parameter for coil design according to an embodiment of the present invention.

According to an embodiment, the storage unit 650 may support the function of providing parameters by being separate from the apparatus for providing a parameter. Here, the storage unit 650 may function as separate mass storage, and may include a control function for performing operations.

Meanwhile, the apparatus for providing a parameter may store information therein by including memory. In an embodiment, the memory is a computer-readable medium. In an embodiment, the memory may be a volatile memory unit, and in another embodiment, the memory may be a non-volatile memory unit. In an embodiment, the storage device is a computer-readable medium. In different embodiments, the storage device may include, for example, a hard disk, an optical disk device, or any other mass storage device.

As described above, when the apparatus for providing a parameter is used, information about parameters may be provided in order to enable a user to easily design a desired coil.

Also, design information may be automatically provided in order to enable a user to quickly generate a coil, and because constraints are considered when the coil is designed, an optimum coil desired by the user may be designed in a restricted environment.

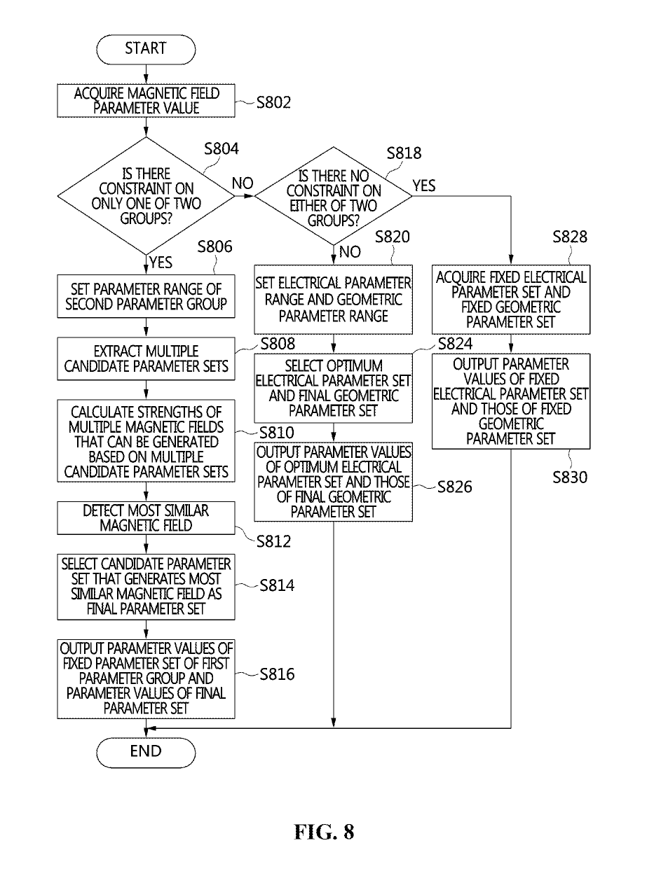

FIG. 7 is a block diagram that shows an example of the control unit illustrated in FIG. 6.

Referring to FIG. 7, the control unit 630 illustrated in FIG. 6 includes a candidate parameter set extraction unit 710, a magnetic field calculation unit 720, and a similar magnetic field detection unit 730.

The candidate parameter set extraction unit 710 extracts multiple candidate parameter sets in order to select a final parameter set therefrom.

Here, the candidate parameter sets may be generated within the parameter range. That is, various parameter sets that can be applied to a coil are generated, and the parameter set that is most suitable for achieving the magnetic field parameter value may be selected as the final parameter set.

Here, among the multiple candidate parameter sets, a candidate parameter set based on which the magnetic field that is closest to the magnetic field parameter value can be generated may be selected as the final parameter set.

The magnetic field calculation unit 720 calculates the strengths of multiple magnetic fields that can be generated based on the fixed parameter set and the multiple candidate parameter sets.

Here, the strength of each of the multiple magnetic fields may be calculated using a Biot-Savart law.

Here, even though the geometry of an arbitrary coil is complicated, the effect of a magnetic field at a certain point generated from the coil may be calculated using the Biot-Savart law. Particularly, when the Boundary Element Method (BEM) or the Finite Element Method (FEM) is used, the effect of a magnetic field may be calculated using an improved computing device; however, this is time-consuming.

Here, because the process of calculating the strength of a magnetic field based on a Biot-Savart law has been described with reference to FIG. 5, a description thereof will be omitted.

The similar magnetic field detection unit 730 detects the most similar magnetic field that satisfies a condition in which the absolute value of the difference between the strength thereof and the magnetic field parameter value is smallest, among the multiple magnetic fields.

Here, among the multiple candidate parameter sets, the candidate parameter set that can generate the most similar magnetic field may be selected as the final parameter set.

For example, assume that an objective function F for calculating the absolute value of the difference between the magnetic field parameter value, which is input by a user, and the strength of each of the multiple magnetic fields is defined, and that all possible parameter sets are defined as multiple domains of the objective function F. Here, a domain is set within the parameter range in order to improve the calculation speed and to avoid being trapped in a local minimum, whereby the total computational load may be decreased and a local minimum error may be prevented. That is, multiple candidate parameter sets corresponding to some of all possible parameter sets may be defined as the domain. Then, when the objective function is calculated, the result thereof may be created in the form of an array. When each value included in this array is called energy, the index of an element containing the minimum energy (cost) in the array is found, whereby the final parameter set may be selected.

FIG. 8 is a flowchart that specifically shows a method for providing a parameter for coil design according to an embodiment of the present invention.

Referring to FIG. 8, in the method for providing a parameter for coil design according to an embodiment of the present invention, a magnetic field parameter value for an arbitrary coil is received from a user at step S802.

Then, whether there is a constraint on only one of the two groups is determined at step S804.

Here, the two groups are an electrical parameter group and a geometric parameter group that are necessary in order to design a coil.

That is, whether there is a constraint only on the electrical parameter group or whether there is a constraint only on the geometric parameter group may be determined.

Here, whether there is a constraint on the electrical parameter group may be determined based on a power supply module for supplying power to the coil, and whether there is a constraint on the geometric parameter group may be determined based on whether the coil has been developed.

When it is determined at step S804 that there is a constraint on only one of the two groups, a parameter range of a second parameter group is set at step S806 based on a fixed parameter set of a first parameter group.

Then, multiple candidate parameter sets within the parameter range are extracted at step S808, and the strengths of multiple magnetic fields that can be generated by applying the multiple candidate parameter sets are calculated at step S810.

Here, the strength of each of the multiple magnetic fields may be calculated using a Biot-Savart law.

Then, among the multiple magnetic fields, the most similar magnetic field that is closest to the magnetic field parameter value input by the user is detected at step S812, and the candidate parameter set that generates the most similar magnetic field is selected as the final parameter set at step S814, among the multiple candidate parameter sets.

Then, the parameter values of the fixed parameter set of the first parameter group and the parameter values of the final parameter set are output to the user at step S816.

Here, the fixed parameter set includes fixed values respectively for multiple first parameters included in the first parameter group, and the final parameter set may include final parameter values respectively for multiple second parameters included in the second parameter group.

Also, when it is determined at step S804 that a condition in which there is a constraint on only one group is not satisfied, whether there is no constraint on either of the two groups is determined at step S818.

When it is determined at step S818 that there is no constraint on either of the two groups, an electrical parameter range and a geometric parameter range are set at step S820.

That is, because there is no fixed parameter, a parameter range for selecting a parameter set for each parameter group may be set.

Then, a final electrical parameter set and a final geometric parameter set are selected at step S824, and the parameter values of the final electrical parameter set and those of the final geometric parameter set are output to the user at step S826.

Also, when it is determined at step S818 that a condition in which there is no constraint on either of the two groups is not satisfied, it is determined that there are constraints on both of them, and a fixed electrical parameter set and a fixed geometric parameter set are acquired at step S828.

In this case, the user may adjust only the voltage and the frequency for the coil.

Then, the parameter values of the fixed electrical parameter set and those of the fixed geometric parameter set are output to the user at step S830.

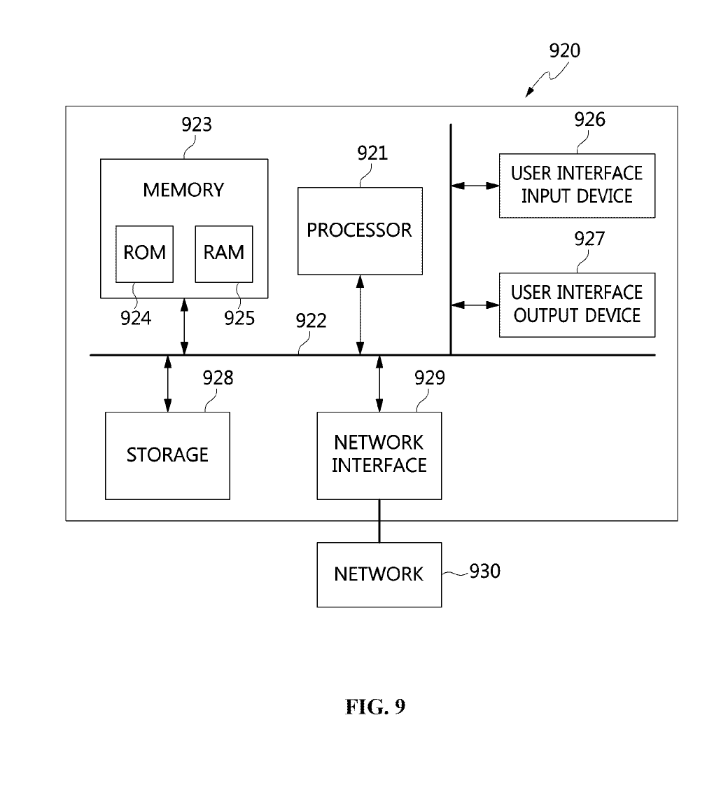

An embodiment of the present invention may be implemented in a computer system, e.g., as a computer readable medium. As shown in FIG. 9, a computer system 920 may include one or more of a processor 921, a memory 923, a user interface input device 926, a user interface output device 927, and a storage 928, each of which communicates through a bus 922. The computer system 920 may also include a network interface 929 that is coupled to a network 930. The processor 921 may be a central processing unit (CPU) or a semiconductor device that executes processing instructions stored in the memory 923 and/or the storage 928. The memory 923 and the storage 928 may include various forms of volatile or non-volatile storage media. For example, the memory may include a read-only memory (ROM) 924 and a random access memory (RAM) 925.

Accordingly, an embodiment of the invention may be implemented as a computer implemented method or as a non-transitory computer readable medium with computer executable instructions stored thereon. In an embodiment, when executed by the processor, the computer readable instructions may perform a method according to at least one aspect of the invention.

According to the present invention, information about parameters may be provided in order to enable a user to easily design a desired coil.

Also, the present invention may automatically provide design information in order to enable a user to quickly generate a desired coil.

Also, the present invention enables an optimum coil desired by a user to be designed in a restricted environment by considering constraints when the coil is designed.

As described above, the apparatus and method for providing a parameter for coil design according to the present invention are not limitedly applied to the configurations and operations of the above-described embodiments, but all or some of the embodiments may be selectively combined and configured, so that the embodiments may be modified in various ways.

What is claimed is:

1. A method for providing a parameter for coil design, comprising:
receiving a magnetic field parameter value for an arbitrary coil from a user;
determining whether there is a constraint on each of an electrical parameter group and a geometric parameter group, which are necessary in order to design the arbitrary coil;
when it is determined that there is a constraint on either the electrical parameter group or the geometric parameter group, setting a parameter range for a second parameter group on which there is no constraint based on a fixed parameter set of a first parameter group on which there is a constraint; and
selecting a final parameter set of the second parameter group for satisfying the magnetic field parameter value within the parameter range and outputting parameter values of the fixed parameter set and the final parameter set to the user.

2. The method of claim 1, wherein outputting the parameter values comprises:
extracting multiple candidate parameter sets for selecting the final parameter set therefrom; and
selecting a candidate parameter set that is capable of generating a magnetic field that is closest to the magnetic field parameter value as the final parameter set, among the multiple candidate parameter sets.

3. The method of claim 2, wherein:
selecting the candidate parameter set comprises:
calculating a strength of each of multiple magnetic fields that are capable of being generated based on the fixed parameter set and the multiple candidate parameter sets; and
detecting a most similar magnetic field that satisfies a condition in which an absolute value of a difference between a strength thereof and the magnetic field parameter value is smallest, among the multiple magnetic fields, and
wherein the candidate parameter set that generates the most similar magnetic field is selected as the final parameter set, among the multiple candidate parameter sets.

4. The method of claim 1, further comprising:
acquiring a fixed electrical parameter set for the electrical parameter group and a fixed geometric parameter set for the geometric parameter group when it is determined that there are constraints on both the electrical parameter group and the geometric parameter group; and
outputting parameter values of the fixed electrical parameter set and parameter values of the fixed geometric parameter set to the user.

5. The method of claim 1, further comprising:
setting an electrical parameter range for the electrical parameter group and a geometric parameter range for the geometric parameter group when it is determined that there is no constraint on any of the electrical parameter group and the geometric parameter group;
selecting a final electrical parameter set of the electrical parameter group for satisfying the magnetic field parameter value within the electrical parameter range and a final geometric parameter set of the geometric parameter group for satisfying the magnetic field parameter value within the geometric parameter range; and
outputting parameter values of the final electrical parameter set and parameter values of the final geometric parameter set to the user.

6. The method of claim 1, wherein the fixed parameter set includes fixed values respectively for multiple first parameters included in the first parameter group, and the final parameter set includes final parameter values respectively for multiple second parameters included in the second parameter group.

7. The method of claim 3, wherein calculating the strength is configured to calculate the strength of each of the multiple magnetic fields using a Biot-Savart law.

8. The method of claim 1, wherein the magnetic field parameter value is a strength of a magnetic field at any coordinates in a region of a magnetic field generated from the arbitrary coil.

9. The method of claim 1, wherein determining whether there is a constraint comprises:
determining whether there is a constraint on the electrical parameter group based on a power supply module for supplying power to the coil; and
determining whether there is a constraint on the geometric parameter group depending on whether the coil has been developed.

10. The method of claim 1, wherein:
the electrical parameter group includes a parameter corresponding to at least one of a maximum voltage, a supplied voltage, a maximum current, and a frequency, and
the geometric parameter group includes a parameter corresponding to at least one of a diameter of the arbitrary coil, an inner radius thereof, and a height or a length thereof.

11. An apparatus for providing a parameter for coil design, comprising:
an input unit for receiving a magnetic field parameter value for an arbitrary coil from a user;
a determination unit for determining whether there is a constraint on each of an electrical parameter group and a geometric parameter group, which are necessary in order to design the arbitrary coil;
a control unit for setting a parameter range for a second parameter group on which there is no constraint based on a fixed parameter set of a first parameter group on which there is a constraint when it is determined that there is a constraint on either the electrical parameter group or the geometric parameter group, and for selecting a final parameter set of the second parameter group for satisfying the magnetic field parameter value within the parameter range; and
an output unit for outputting parameter values of the fixed parameter set and the final parameter set to the user.

12. The apparatus of claim 11, wherein:
the control unit comprises a candidate parameter set extraction unit for extracting multiple candidate parameter sets for selecting the final parameter set therefrom; and
the control unit selects a candidate parameter set that is capable of generating a magnetic field that is closest to the magnetic field parameter value as the final parameter set, among the multiple candidate parameter sets.

13. The apparatus of claim 12, wherein
the control unit further comprises:
a magnetic field calculation unit for calculating a strength of each of multiple magnetic fields that are capable of being generated based on the fixed parameter set and the multiple candidate parameter sets; and
a similar magnetic field detection unit for detecting a most similar magnetic field that satisfies a condition in which an absolute value of a difference between a strength thereof and the magnetic field parameter value is smallest, among the multiple magnetic fields, and
the control unit selects a candidate parameter set that generates the most similar magnetic field as the final parameter set, among the multiple candidate parameter sets.

14. The apparatus of claim 11, wherein, when it is determined that there are constraints on both the electrical parameter group and the geometric parameter group, the output unit outputs parameter values of a fixed electrical parameter set for the electrical parameter group and parameter values of a fixed geometric parameter set for the geometric parameter group to the user.

15. The apparatus of claim 11, wherein, when there is no constraint on any of the electrical parameter group and the geometric parameter group, the control unit sets an electrical parameter range for the electrical parameter group and a geometric parameter range for the geometric parameter group and selects a final electrical parameter set of the electrical parameter group for satisfying the magnetic field parameter value within the electrical parameter range and a final geometric parameter set of the geometric parameter group for satisfying the magnetic field parameter value within the geometric parameter range.

16. The apparatus of claim 15, wherein, when there is no constraint on any of the electrical parameter group and the geometric parameter group, the output unit outputs parameter values of the final electrical parameter set and parameter values of the final geometric parameter set to the user.

17. The apparatus of claim 11, wherein the fixed parameter set includes fixed values respectively for multiple first parameters included in the first parameter group, and the final parameter set includes final parameter values respectively for multiple second parameters included in the second parameter group.

18. The apparatus of claim 13, wherein the magnetic field calculation unit calculates the strength of each of the multiple magnetic fields using a Biot-Savart law.

19. The apparatus of claim 11, wherein the magnetic field parameter value is a strength of a magnetic field at any coordinates in a region of a magnetic field generated from the arbitrary coil.

20. The apparatus of claim 11, wherein:
the electrical parameter group includes a parameter corresponding to at least one of a maximum voltage, a supplied voltage, a maximum current, and a frequency, and
the geometric parameter group includes a parameter corresponding to at least one of a diameter of the arbitrary coil, an inner radius thereof, and a height or a length thereof.
